(19) United States
(12) Patent Application Publication
(10) Pub. No.: US 2023/0143750 A1
(43) Pub. Date: May 11, 2023

(54) FEED-FORWARD AND UTILIZATION OF HEIGHT INFORMATION FOR METROLOGY TOOLS

(71) Applicant: International Business Machines Corporation, Armonk, NY (US)

(72) Inventor: Daniel Schmidt, Niskayuna, NY (US)

(21) Appl. No.: 17/520,933

(22) Filed: Nov. 8, 2021

(51) Int. Cl. G03F 7/20

(52) U.S. Cl. CPC G03F 7/70641; G03F 7/70625; G03F 7/70666

(57) ABSTRACT

Methods and systems for configuring a metrology tool are described. A processor can receive a height map of a sample from an apparatus configured to generate wafer height maps. The received height map can indicate height information of a plurality of features on a surface of the sample. The plurality of features can be located on a plurality of focal planes. The processor can generate settings for the metrology tool based on the height map of the sample.

### BACKGROUND

The present application relates systems and methods for adjusting performance of a semiconductor metrology tool. In one aspect, the present application relates more particularly to configuring settings of an overlay metrology tool using height maps of a semiconductor devices.

Fabrication of semiconductor devices (e.g., integrated circuits (IC), logic devices, memory device, etc.) can include processing a substrate or a semiconductor wafer (“wafer”) using a large number of semiconductor fabrication processes to form various features and multiple levels of the semiconductor devices. For example, lithography is a semiconductor fabrication process that transfers a circuit pattern on a mask or a reticle onto a wafer coated with resist materials (e.g., photoresist). Metrology tools can be used for measuring wafer characteristics such as a dimension (e.g., line width, thickness, etc.) of circuit pattern layers formed on the wafer during the manufacturing process, and a performance of the manufacturing process can be evaluated using the measured wafer characteristics. Metrology tools can also be used at various steps during the semiconductor manufacturing process to monitor and control the manufacturing process, such as identifying overlay errors that occur when there is misalignment between any of the circuit patterns on same and/or different circuit pattern layers formed on the wafer.

### SUMMARY

In an embodiment, a method for configuring a metrology tool is generally described. The method can include receiving a height map of a sample from an apparatus configured to generate wafer height maps. The height map can indicate height information of a plurality of features on a surface of the sample. The plurality of features can be located on a plurality of focal planes. The method can further include generating settings for the metrology tool based on the height map of the sample.

In an embodiment, a system for configuring a metrology tool is generally described. The system can include a metrology tool, a memory, an apparatus, and a processor connected to the metrology tool, the memory, and the apparatus. The apparatus can be configured to generate a height map that indicates height information of a plurality of features on a surface of a sample. The plurality of features can be located on a plurality of focal planes. The apparatus can be further configured to send the generated height map to the processor. The processor can be configured to receive the height map from the apparatus. The processor can be further configured to generate settings for the metrology tool based on the height map.

In an embodiment, a computer program product for configuring a metrology tool is generally described. The computer program product can include a computer readable storage medium having program instructions embodied therewith. The program instructions can be executable by a processing element of a device to cause the device to receive a height map of a sample from an apparatus configured to generate wafer height maps. The height map can indicate height information of a plurality of features on a surface of the sample. The plurality of features can be located on a plurality of focal planes. The program instructions can be further executable by a processing element of a device to cause the device to generate settings for the metrology tool based on the height map of the sample.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram illustrating an example system that can implement feed-forward and utilization of height information for metrology tools in one embodiment.

FIG. 2 is a diagram illustrating an example height map that can be used for implementing the example system shown in FIG. 1 in one embodiment.

FIG. 3 is a diagram illustrating a wafer sample having a surface with varying heights in one embodiment.

FIG. 4 is a diagram illustrating an example metrology tool that can utilize the example system shown in FIG. 1 in one embodiment.

FIG. 5 is a diagram illustrating another example metrology tool that can utilize the example system shown in FIG. 1 in one embodiment.

FIG. 6 is a flow diagram illustrating a process that can implement feed-forward and utilization of height information for metrology tools in one embodiment.

FIG. 7 illustrates a schematic of an example computer or processing system that may implement feed-forward and utilization of height information for metrology tools in one embodiment.

### DETAILED DESCRIPTION

If the measured wafer characteristics are unacceptable, settings for the manufacturing process can be adjusted such that additional wafers, or additional circuit pattern layers, to be manufactured by the same manufacturing process can be processed using improved settings. For example, the measured wafer characteristics can be used for determining an appropriate position of a wafer stage holding the wafer and/or adjusting optical tools to alter illumination angles being used by metrology tools.

Wafer characteristic measurements performed by overlay metrology tools can specify how accurately a first circuit pattern layer aligns with respect to a second circuit pattern layer, where the second circuit pattern layer can be disposed above or below the first circuit pattern layer. The wafer characteristic measurements from overlay metrology tools can also specify how accurately a first circuit pattern aligns with a second circuit pattern disposed on the same layer. If the two layers of circuit patterns are properly formed, then no adjustments may need to be made to the lithography apparatus that formed the layers on the wafer. If the two layers or patterns are not properly formed, then it may be necessary to adjust various settings of the lithography apparatus that formed layers on the wafer.

In one embodiment, overlay metrology tools can be microscopy tools, and the overlay measurements may be based on images of different parts of the wafer captured by the overlay metrology tool. In an aspect, having sharpness of specific circuit pattern features in the captured image can help in obtaining precise overlay measurements. A sharpness of specific features in an image captured by the overlay metrology tool can be based on a focus setting of the overlay metrology tool. A focus setting can allow the overlay metrology tool to capture an image of a sample (e.g., a wafer) with features at a specific height level (e.g., focal plane) being in focus, and features at other height levels (e.g., other focal planes) being out of focus (e.g., blurred). The focus setting of the overlay metrology tool can be based on, for example, distances between a target (e.g., a sample, or a wafer surface) and a probe (e.g., mechanical probe) and/or light source that emits light beams for image capturing). Features on a sample can be located at different height levels, and different focus settings can allow features on the different height levels to be in focus (e.g., sharper relative to features at ither height levels).

However, overlay metrology tools can be relatively slow because after each circuit pattern layer is formed on the wafer, the overlay metrology tools perform a move-acquire-measure (MAM) process (e.g., an interferometric-type measurement). This MAM process can include moving the wafer to a position where a focus setting of the overlay metrology tool can be optimal (e.g., obtaining images of the wafer with optimal sharpness), acquiring images of the wafer, and performing measurements based on the acquired images. In an aspect, the overlay metrology tool may perform measurement on using images of the wafer that were captured using a limited number of focus settings in order to save cost (e.g., time and power). The limited number of focus settings may provide an insufficient amount of information since some features that are not focused by the limited number of focus settings can be out of focus (e.g., blurred). For example, the overlay metrology tool can use a limited number of focus settings to obtain images of the wafer surface, where the wafer surface can include features distributed at a number of different height levels (or focal planes). The number of different height levels can be significantly greater than the limited number of focus settings used. The significant difference between the number of focus settings and the number of height levels reduces can neglect features that are on height levels not focused by the limited focus settings. It may be relatively time consuming to determine a focus setting for every height level of the wafer surface.

In an aspect, the MAM time can be reduced by using previously known problem areas on the wafer surface to remove the step of obtaining updated height information. However, this approach does not consider variations (e.g., temperature and process variations) in the manufacturing process. It is desirable to reduce the time needed for MAM process in order to improve a speed of the overlay metrology tools. The improved speed can allow the overlay metrology tools to operate with additional different focus settings that can accommodate the different heights across the wafer surface. The additional focus settings can improve an overall focus of the overlay metrology tool and allow the overlay metrology tool to obtain images with more focused or sharper features at different height levels.

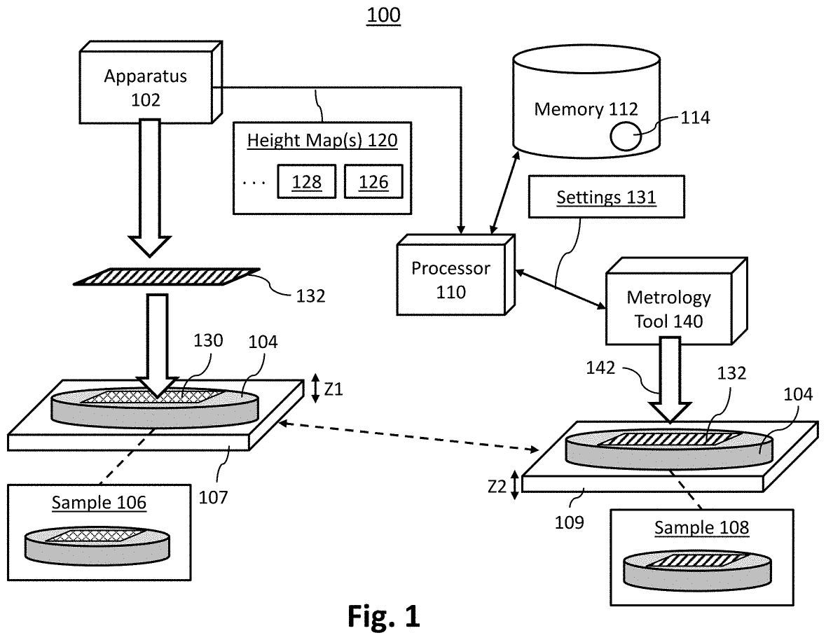

FIG. 1 is a diagram illustrating an example system 100 that can implement feed-forward and utilization of height information for metrology focus control in one embodiment. The system 100 can include an apparatus 102, a processor 110, a memory 112, and a metrology tool 140. In one embodiment, the processor 110 and the memory 112 can be part of a computing device. For example, the processor 110 can be a microprocessor or a central processing unit (CPU) of a computer device such as desktop computer, a server, a laptop computer, a tablet device, and/or other types of computing devices that can be configured to process instructions pertaining the methods described herein. The memory 112 can be a memory block including one or more memory devices, and can include, for example, volatile and/or non-volatile memory devices. The memory 112 can be configured to store a set of instructions 114, where the set of instructions 114 can include source code and executable code relating to various algorithms and techniques that can be implemented by the processor 110 to perform the methods described herein. In another embodiment, the processor 110 and memory 112 can be parts of the metrology tool 140.

The apparatus 102 can be a lithography system or other standalone system or device that can generate a plurality of height maps 120 of one or more samples, such as wafers and/or semiconductor devices. The apparatus 102 can include a wafer stage 107 that can be a platform, a board, a table, or a structure that can support a wafer 104 and hold the wafer 104 in place. The apparatus 102 can be configured to implement a lithography process, which can include light exposure process, to transfer circuit patterns from reticles onto the wafer 104, where the lithography process can be performed on each reticle sequentially. For example, in the example shown in FIG. 1, the apparatus 102 can transfer a circuit pattern 130 from a first reticle onto the wafer 104, forming a sample 106, and transfer another circuit pattern 132 from another reticle onto the sample 106 to form another sample 108.

For each layer of circuit pattern being transferred onto the wafer 104, the apparatus 102 can obtain updated height information of the formed sample (e.g., the wafer 104 with a new layer of circuit pattern). For example, in response to forming the sample 106 having the circuit pattern 130, the apparatus 102 can obtain height information of the sample 106 and generate a height map 126 of the sample 106. The height information indicated by the height map 126 can be, for example, a vertical position or distance between a top surface of the sample 106 and a top surface of the wafer stage 107. The height map 126 can include visual indicators, or coded indicators (e.g., coded with different pixel values or shading), to indicate the calculated height information of the plurality of features on the surface of the sample 106. In one embodiment, the apparatus 102 can use the height information in the height map 126 to align the reticle having the circuit pattern 132 (e.g., the next layer of circuit pattern) to ensure that the circuit pattern 132 is transferred correctly (e.g., in terms of spacing and alignment) onto the sample 106.

In response to forming the sample 108 with the circuit pattern 132, the apparatus 102 can obtain another set of height information of the sample 108 and generate another height map 128 for the sample 108. The height information indicated by the height map 128 can be, for example, a vertical position or distance between a top surface of the sample 108 and a top surface of the wafer stage 107. The height map 128 can include visual indicators, or coded indicators (e.g., coded with different pixel values or shading), to indicate the calculated height information of the plurality of features on the surface of the sample 108. In one embodiment, the apparatus 102 can use the height information in the height map 128 to align the reticle for the next layer of circuit pattern to ensure that the circuit pattern of the next reticle is transferred correctly onto the sample 108.

After the apparatus 102 uses a height map to align circuit pattern from a next reticle, the processor 110 can utilize the height map to perform overlay metrology that checks whether the circuit pattern layers being formed on the wafer 104 are aligned with one another. In the example shown in FIG. 1, in response to generating a height map for each sample with a newly formed circuit pattern layer, the apparatus 102 can send the generated height map to the processor 110. For example, in response to generating the height map 126, the apparatus 102 can send the height map 126 to the processor 110. In one embodiment, the apparatus 102 can send the height map 126 to the processor 110 before transferring the circuit pattern 132 onto the sample 106. In response to generating the height map 128, the apparatus 102 can send the height map 128 to the processor 110. The apparatus 102 can send to the processor 110, height maps generated for each circuit pattern layer being formed on the wafer 104 by a lithography process. If a semiconductor device includes N layers of circuit pattern on a wafer, the apparatus 102 can send N height maps to the processor 110 in the manufacturing process of the semiconductor device.

The processor 110 can receive the height maps 120 from the apparatus 102 and store the received height maps in the memory 112. The processor 110 can generate settings 131 using the height maps stored in the memory 112, where the settings 131 can be used for configuring the metrology tool 140. In one embodiment, if the processor 110 is a part of the metrology tool 140, then the metrology tool 140 can be configured to generate the settings 131. In another embodiment, if the processor 110 is a part of a device separated from the metrology tool 140, then the processor 110 can generate the settings 131 based on the height maps 120 and send the settings 131 to the metrology tool 140 to configure the metrology tool 140. In one or more embodiment, the processor 110 can obtain a current setting of the metrology tool 140 and generate the settings 131 based on the height maps 120 and the obtained current setting. For example, the current setting can include current positions of lenses, a wafer stage 109 of the metrology tool 140, sensors, probes, mirrors, reflectors, etc., and the processor 110 can adjust these current settings based on the height maps 120 to generate the settings 131.

Samples, such as the sample 108, can be transported from the apparatus 102 to the metrology tool 140, or from the wafer stage 107 to the wafer stage 109 of the metrology tool 140. In response to the transport, the apparatus 102 can provide the height map 128 to the processor 110 and/or the metrology tool 140. By providing the height map 128 to the processor 110, the metrology tool 140 can avoid, a step of performing a MAM process to scan the sample 108 to obtain height information of the transported sample 108. An elimination of the step to obtain height information at the metrology tool 140 can reduce the MAM time needed for overlay metrology. Further, by having the processor 110 store each and every height map 120 in the memory 112, the processor 110 can selectively provide different height maps for different types of metrology tools. For example, more than one metrology tool (e.g., in addition to metrology tool 140) can be connected to the processor 110, and the connected metrology tools can access the height maps 120 stored in the memory 112. Furthermore, by having the processor 110 store each and every height map 120 in the memory 112, the processor 110 can select specific problem areas on the samples that may require adjustment in focus settings of the metrology tool 140 to obtain sharper images of these problem areas.

In one embodiment, the processor 110 can be configured to modify the height maps 120 according to a height difference between the wafer stage 107 of the apparatus 102 and the wafer stage 109 of the metrology tool 140. For example, if a thickness of the wafer stage 107 is Z1 and a thickness of the wafer stage 109 is Z2. If Z1 is greater than Z2, then the processor 110 can add a difference Z1−Z2 to the height information in the height maps 120. If Z1 is less than Z2, then the processor 110 can remove a difference Z2-Z1 from the height information in the height maps 120. If Z1 is equal to Z2, then the processor 110 may not need to adjust the height information in the height maps 120. In another embodiment, a calibration map may be stored in the memory 112, where the calibration map can be a height map indicating height differences (e.g., height signature differences) of wafer chucks being used for chucking wafers (e.g., holding the wafer in place) on the wafer stage 109. The calibration map can be used for compensating the differences between the thickness of the wafer stage 107 and the wafer stage 109.

In one embodiment, a height map of a most recent layer of circuit pattern (e.g., height map 128, instead of height map 126) can be used by the metrology tool 140 to determine settings such as beam incident angle, illumination intensity, image sensor position, lens positions, wafer stage position, (e.g., wafer stage 109), and/or other settings associated with the metrology tool 140. In another embodiment, if the metrology tool 140 requires information of more than one layers of circuit pattern to perform overlay measurements, the metrology tool 140 can retrieve more than one height map from the memory 112. For example, to perform overlay measurement on the sample 108 (e.g., identify overlay errors between the circuit patterns 130, 132 formed on the wafer 104), the metrology tool 140 can obtain the height maps 126, 128, from the memory 112. The metrology tool 140 can determine a difference between the height maps 126, 128, to estimate or determine a layer height of the layer having the circuit pattern 132. The estimated layer height can be used for correcting misregistration readings according to the height variations across the sample 108. Further, if the metrology tool 140 is a diffraction-based overlay metrology tool, the height differences between the height maps 126, 128 can be used for determining, estimating, and/or compensating the intensity difference between diffracted beams being used for overlay measurements.

In an embodiment, the storage of multiple height maps obtain during the manufacture process of a semiconductor device can provide a centralized and flexible system for different metrology tools, and different types of metrology tools, to access the stored height maps and to operate with higher efficiency (e.g., by eliminating the step to obtain height information of devices).

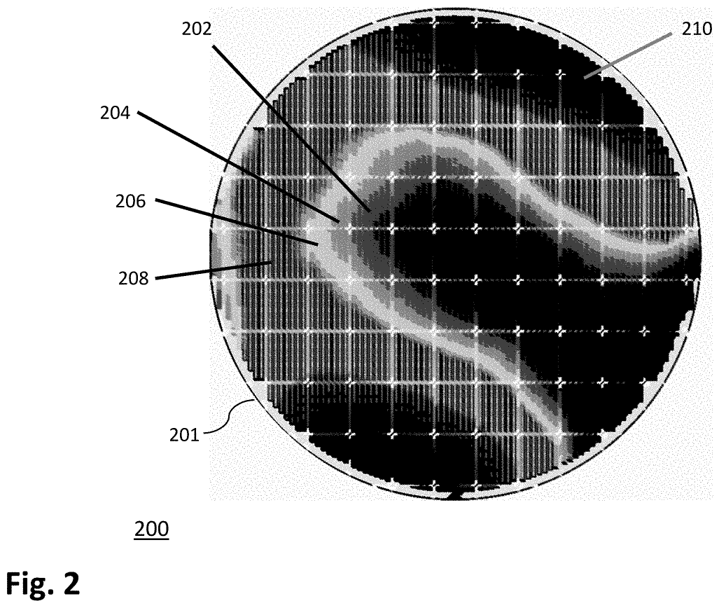

FIG. 2 is a diagram illustrating an example height map that can be used for implementing the example system shown in FIG. 1 in one embodiment. An example height map 200 of a wafer sample 201 is shown in FIG. 2, where the height map 200 can be among the height maps 120 of FIG. 1. The height map 200 can include visual indicators, such as shadings 202, 204, 206, 208, 210 having different pixel values. Each shade can represent a height value or height level, or a range of height levels, of a surface of the wafer sample 201. The height levels can be, for example, distances between a surface of the wafer sample 201 and a surface of a wafer stage (e.g., wafer stage 109 in FIG. 1). For example, a shade 202 can represent the portion of the wafer sample 201 having the highest focal plane, and a shade 210 can represent the portion of the wafer sample 201 having the lowest focal plane.

In one embodiment, a specific focus setting can allow an overlay metrology tool (e.g., metrology tool 140 in FIG. 1) to capture an image where the features in the shade 206 are in focus, but features in the other shades can be out of focus. This is due to the height difference on the surface of the sample wafer causing difference in focus settings such as distances between a light source, sensors, or other components of the overlay metrology tool with the surface of the sample wafer. By providing a height map, such as height map 200, to an overlay metrology tool, the overlay metrology tool may not need to perform the steps in the MAM process to obtain height information of the wafer sample 201 and seek best focus points for different height levels. A processor (e.g., processor 110 in FIG. 1) or the overlay metrology tool can identify the shadings 202, 204, 206, 208, 210 in the height map 200 and generate focus settings of the overlay metrology tool based on the identified shadings (to be described in more detail below). As a result of using a provided height map, the step to obtain height information and seeking focus points for overlay measurements can be skipped, reducing the time being used for the entire overlay measurement process.

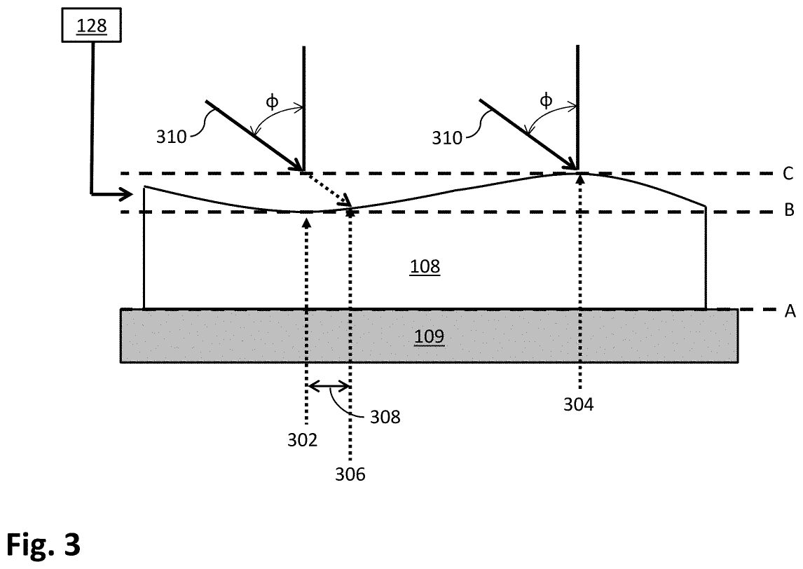

FIG. 3 is a diagram illustrating a wafer sample having a surface with varying heights in one embodiment. In an example shown in FIG. 3, the sample 108 can be situated on the wafer stage 109. The sample 108 can have a surface that has varying heights from a surface of the wafer stage 109. A feature 302 can be located at a height level or a focal plane B, and have a height of B−A. A feature 304 can be located at a height level or a focal plane C, and have a height of C−A, where the feature 304 is at a higher height level than the feature 302. In one embodiment, the metrology tool can use a focus setting for the focal plane C to capture an image of the sample 108, where the captured image can have the feature 304 (and other features on the focal plane C) in focus, but the feature 302 (and other features not on focal plane C) out of focus. For example, the focus setting for focal plane C can have a light source illuminating a light beam 310 onto the sample 108 at an incident angle ϕ. A failure to use another focus setting for the focal plane B can cause the overlay metrology tool to obtain inaccurate measurements relating to the feature 304. For example, the same light beam 310 being illuminated at the incident angle ϕ can miss the feature 302 and illuminate another feature 306, causing a lateral shift of focus for the feature 302 by a lateral distance 308, and this lateral distance can indicate an out of focus degree of the feature 302. To capture an image of the sample 108 where the feature 302 is focused, the angle ϕ can be adjusted to focus the feature 302.

A processor (e.g., processor 110 in FIG. 1) can receive the height map 128 of the sample 108 and use the height map 128 to determine focus settings for an overlay metrology tool (e.g., metrology tool 140 in FIG. 1). The height map 128 can include visual indicators, such as different pixel values or shades, that can be read and interpreted by the processor to generate settings for the overlay metrology tool (e.g., see height map 200 in FIG. 2). In one embodiment, in response to receiving the height map 128, the processor can perform a global offset determination process to determine a plurality of focus settings for the metrology tool to capture optimal images of different portions with different heights of the sample 108.

The global offset determination process can begin with determining an initial focus setting for one specific height level or focal plane of the sample 108. For example, the processor can use the feature 304 to determine the initial focus setting. The processor can use multiple focus settings to capture multiple images of the sample 108 and identify a focus setting that captures an image with the feature 304 in focus. The processor can assign the identified focus setting to the focal plane C and can set the identified focus setting as a reference setting. The processor can use the height map to calculate or determine offsets from the reference setting to generate a plurality of focus settings for other height levels or focal planes. For example, the reference setting can set a light source to illuminate the light beam 310 at the angle of incidence ϕ. To determine a focus setting for focal plane B, the processor can determine a height difference between the focal planes B and C, which is C−B, and determine a lateral shift (e.g., lateral distance 308) based on the height difference. The processor can generate a focus setting for the focal plane B by adjusting the reference setting based on the height difference C−B. For example, the processor can determine a new value of ϕ based on the height difference C−B and the lateral distance 308. In one embodiment, the angle of incident can be determined based on the expression:

$$tan ( ϕ ) = \frac{Height difference}{Lateral Shift}$$

The angle of incident ϕ can be determined or adjusted by obtaining the height difference from the height map. The adjusted angle can be part of the settings 131 generated by the processor 110 shown in FIG. 1.

Note that other settings that can affect the focus of the overlay metrology tool can be determined by the processor using the height information in the height map 128 as well, such as position of the wafer stage 109, illumination intensity, mirror or reflector positions, probe positions, etc. The processor can continue to determine different focus settings for different focal planes on the sample 108. In one embodiment, if the height map includes M different shades representing M different ranges of height values, then the processor can generate M different focus settings. The overlay metrology tool can be configured to switch among the M focus settings as the overlay metrology tool captures images of the sample 108, where the captured images can have different features in focus. By using the height map 128 to determine different focus settings, the steps to scan the sample 108 to obtain height information and to seek best focus points for different heights can be removed. The processor can repeat the global offset determination process, and the determination of different focus settings, for each sample (e.g., each circuit pattern layer formed for a semiconductor device) being transported to the overlay metrology tool during the manufacturing process of the semiconductor device.

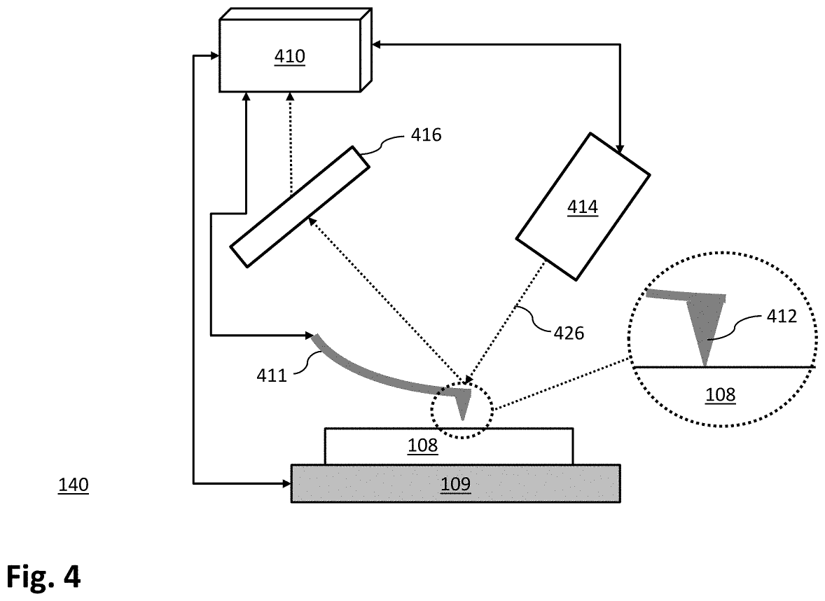

Further, the height maps can allow the processor 110 to generate settings that can improve a performance of different types of metrology tools. In one embodiment, the height maps can be provided to the processor 110 to generate settings for atomic force microscopy (AFM) metrology tools that can improve probe engagement speed (described below in FIG. 4).

In another embodiment, the metrology tool 140 can be optical metrology tools, such as ellipsometry, scatterometry, diffraction based, and/or other types of optical metrology tools that utilized a light source (e.g., laser) to illuminate light beams on a sample at a non-normal angle. The height maps be used for adjusting the illumination direction to improve lateral shift errors in overlay measurements, and may mitigate the risk of shifting between two best focus points due to the contrast reversal secondary peaks.

For example, an ellipsometry metrology tool can include a light source that emits electromagnetic radiation, where the emitted electromagnetic radiation is linearly polarized by a polarizer. The emitted electromagnetic radiation can pass through an optional compensator and falls onto a sample. The sample surface can reflect the radiation, and the reflected radiation can pass through a compensator and another polarizer before being detected by a detector. The processor 110 can use the height map 128 to determine different values of the angle of incidence ϕ that provide optimal focus for different focal planes on the surface of the sample 108. The processor 110 can further determine positions of the light source and the wafer stage 109 of the ellipsometry metrology tool that will cause the emitted radiation to fall on different focal planes of the sample 108 at the determined values of the angle of incidence ϕ. For example, if the processor 110 identify M different shades in the height map 128, the processor 110 can generate M settings (e.g., settings 131) for the ellipsometry metrology tool. The M settings can include M different values of ϕ and M combinations of positions of the light source and the wafer stage 109 of the ellipsometry metrology tool. The ellipsometry metrology tool can switch among the M settings during scanning of the sample 108 and can capture images of the sample 108 using the M settings, where the captured images can have different features in focus. The processor 110 can generate the settings 131 for other optical metrology tools in a similar fashion. The processor 110 can use the height maps to adjust illumination direction of light sources to improve lateral shift errors in overlay measurements.

FIG. 4 is a diagram illustrating an example metrology tool that can utilize the example system shown in FIG. 1 in one embodiment. In the example shown in FIG. 4, the metrology tool 140 can be an atomic force microscopy (AFM) metrology tool. The AFM metrology tool can include a processor 410, a cantilever beam 411, a probe 412, a laser 414, and a photodiode 416. In one embodiment, the processor 410 can be the processor 110 shown in FIG. 1. An AFM metrology tool can utilize a type of scanning probe microscopy (SPM). Information of a sample is gathered by physically contacting the surface of the sample with a mechanical probe, such as the probe 412. The cantilever beam 411 can be attached to the probe 412, and in one embodiment, a piezoelectric element can oscillate the cantilever beam 411 to control movements of the probe across the surface of the sample 108. In one embodiment, the processor unit 410 can be the processor 110 shown in FIG. 1.

The wafer stage 109 can be moved in a two-dimensional space or three-dimensional space in order to move the sample 108 under the probe 412. The cantilever beam 411 can oscillate to cause the probe 412 to contact the surface of the sample 108 as the sample 108 moves with the wafer stage 109. The oscillation of the cantilever beam 411 can be recorded by the processor 410. In one embodiment, to generate images of the sample 108, the laser 414 can emit light into the probe 412, and the probe 412 can reflect the laser light to the photodiode 416. As the cantilever beam 411 oscillates, the probe 412 also oscillates, and the movement of the probe 412, caused by the oscillation of the probe 412, can change the amount of laser light reflected into the photodiode 416. The processor 410 can use the recorded oscillation of the cantilever beam 411, the reflected light detected by the photodiode 416, and the movement of the wafer stage 109 to obtain information that can be rendered into an image of the surface of the sample 108.

In one embodiment, control of the cantilever beam 411 can affect an operation of the AFM metrology tool. For example, the probe 412 needs to contact the sample 108 very gently and carefully to prevent damaging the sample 108. The oscillation of the cantilever beam 411 can be controlled at a relatively slow pace in order to prevent damaging the sample 108. However, slow rate of scanning during AFM imaging often leads to thermal drift in the generated images. It is desirable to speed up the probe engagement of the probe 412 while preventing damage to the sample.

By providing a height map (e.g., height map 128 of sample 108 in FIG. 1), the height information of the sample 108 can be used for predetermining a position of the probe 412. For example, if a current position of the probe 412 is in contact with the feature 302 (see FIG. 3), and the next feature to be measured is feature 304, then the processor 410 can control the cantilever beam 411 to raise the probe 412 by approximately C−B (e.g., height difference of the features 302, 304) according to the height map 128. By using the height map 128, the probe engagement speed for the probe 412 can be increased, and the height information can provide a position of the probe 412 that may reduce the risk of damaging the sample 108.

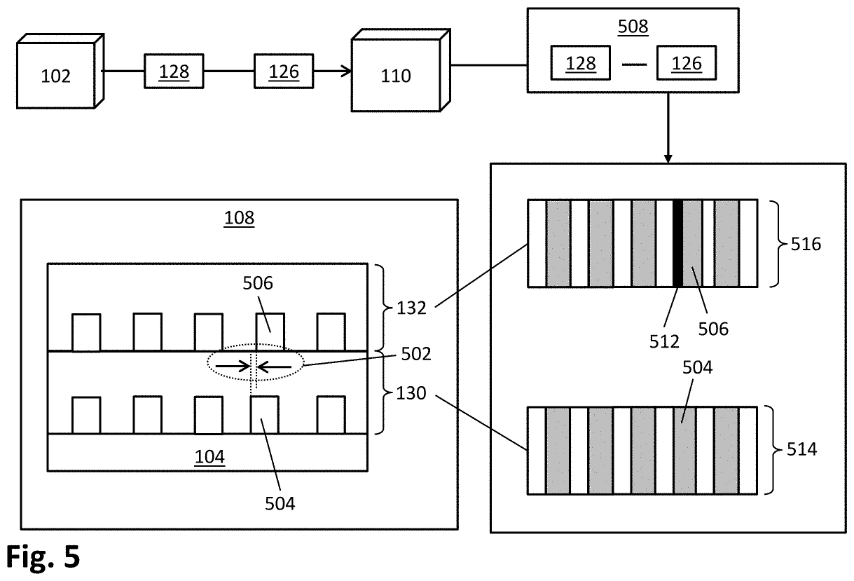

FIG. 5 is a diagram illustrating another example metrology tool that can utilize the example system shown in FIG. 1 in one embodiment. In the example shown in FIG. 5, in response to the metrology tool 140 receiving the sample 106 (see FIG. 1) from the apparatus 102, the processor 110 can scan a surface of the sample 106 to generate a line profile 514 that emphasizes the features or components, such as a feature 504, on the circuit pattern 130 formed on the wafer 104. In response to the metrology tool 140 receiving the sample 108 from the apparatus 102, the processor 110 can scan a surface of the sample 108 to generate a line profile 516 that emphasizes the features or components, such as a feature 506, on the circuit pattern 132 formed on the circuit pattern 130 and the wafer 104. In one embodiment, if there are overlay errors between the consecutive circuit pattern layers 130, 132, the overlay errors can be visible in the line profile 516. For example, an overlay error 502 between the circuit pattern layers 130, 132, can be shown in a shade 512 different from the shade of the features on the circuit pattern layer 132.

Further, in response to the metrology tool 140 receiving the sample 106 from the apparatus 102, the processor 110 can receive the height map 126 from the apparatus 102. In response to the metrology tool 140 receiving the sample 108 from the apparatus 102, the processor 110 can receive the height map 128 from the apparatus 102. The processor 110 can determine a difference 508 between the height maps 126, 128, where the difference 508 can be another height map emphasizing differences between the height maps 126, 128. The processor 110 use the difference 508 to verify and/or correct any misregistration readings in the line profiles 516, 518 to get a more accurate overlay reading across the sample 108. The usage of the height difference can be applicable to image-based metrology tools as well, such as critical dimension scanning electron microscope (CDSEM) and diffraction-based metrology tools, or other metrology tools that may utilize images of consecutive layers to perform overlay measurements.

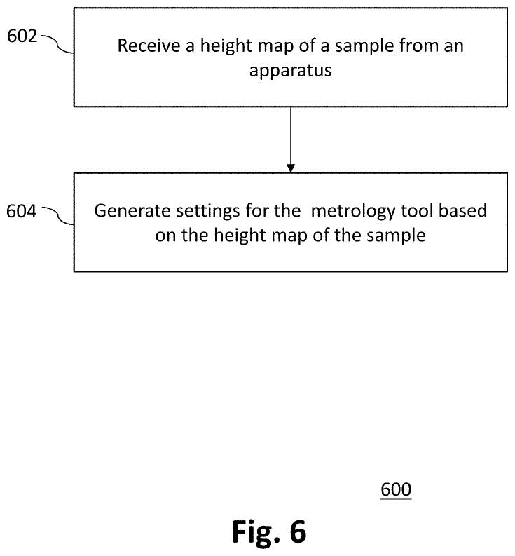

FIG. 6 is a flow diagram illustrating a process 600 that can implement feed-forward and utilization of height information for metrology focus control in one embodiment. The example process 600 may include one or more operations, actions, or functions as illustrated by one or more of blocks 602, 604, and/or 606. Although illustrated as discrete blocks, various blocks may be divided into additional blocks, combined into fewer blocks, eliminated, performed in different order, or performed in parallel, depending on the desired implementation.

The process 600 can be implemented by a processor to configure a metrology tool. The process 600 can being at bloc 602. At block 602, the processor can receive a height map of a sample from an apparatus configured to generate wafer height maps. The height map can indicate height information of a plurality of features on a surface of the sample. The plurality of features can be located on a plurality of focal planes. In one embodiment, the height map can be among a plurality of height maps, and each one of the plurality of height maps can correspond to a circuit pattern formed on the sample. In one embodiment, the processor can store the height map in a memory device. In one embodiment, the processor can adjust the height map based on a height difference between a wafer stage of the apparatus and a wafer stage of the metrology tool. In one embodiment, the height map can correspond to a most recent circuit pattern layer formed on the sample.

The process 600 can proceed from block 602 to block 604. At block 604, the processor can generate settings for the metrology tool based on the height map of the sample. In one embodiment, the generation of the settings for the metrology tool can include determining a plurality of focus settings that cause the metrology tool to focus on the plurality of focal planes. In one embodiment, the processor can identify a specific feature on the surface of the sample. The processor can determine a specific setting for the metrology tool that captures an image of the sample focusing on the specific feature. The processor can determine a plurality of settings for the metrology tool based on the specific setting and the height map. In one embodiment, the settings can include a plurality of positions of a light source of the metrology tool. The plurality of positions of the light source can correspond to the plurality of focal planes. Each position among the plurality of positions of the light source can cause the metrology tool to capture an image of the sample including features located on a corresponding focal plane being in focus.

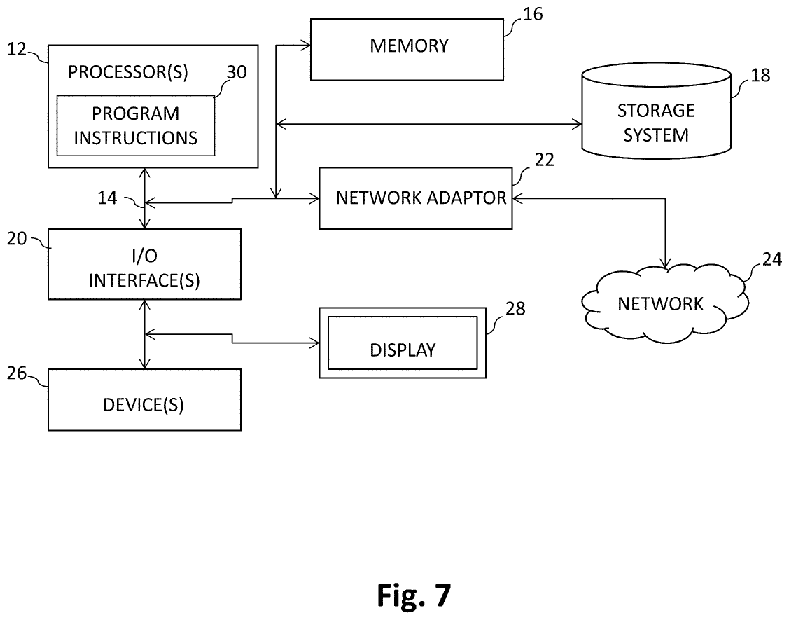

FIG. 7 illustrates a schematic of an example computer or processing system that may implement feed-forward and utilization of height information for metrology focus control in one embodiment. The computer system is only one example of a suitable processing system and is not intended to suggest any limitation as to the scope of use or functionality of embodiments of the methodology described herein. The processing system shown may be operational with numerous other general purpose or special purpose computing system environments or configurations. Examples of well-known computing systems, environments, and/or configurations that may be suitable for use with the processing system shown in FIG. 7 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The computer system may be described in the general context of computer system executable instructions, such as program modules, being run by a computer system. Generally, program modules may include routines, programs, objects, components, logic, data structures, and so on that perform particular tasks or implement particular abstract data types. The computer system may be practiced in distributed cloud computing environments where tasks are performed by remote processing devices that are linked through a communications network. In a distributed cloud computing environment, program modules may be located in both local and remote computer system storage media including memory storage devices.

The components of computer system may include, but are not limited to, one or more processors or processing units 12, a system memory 16, and a bus 14 that couples various system components including system memory 16 to processor 12. The processor 12 may include a module 30 that performs the methods described herein. The module 30 may be programmed into the integrated circuits of the processor 12, or loaded from memory 16, storage device 18, or network 24 or combinations thereof.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. Computer system may further include other removable/non-removable, volatile/non-volatile computer system storage media. By way of example only, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

Computer system may also communicate with one or more external devices 26 such as a keyboard, a pointing device, a display 28, etc.; one or more devices that enable a user to interact with computer system; and/or any devices (e.g., network card, modem, etc.) that enable computer system to communicate with one or more other computing devices. Such communication can occur via Input/Output (I/O) interfaces 20.

Still yet, computer system can communicate with one or more networks 24 such as a local area network (LAN), a general wide area network (WAN), and/or a public network (e.g., the Internet) via network adapter 22. As depicted, network adapter 22 communicates with the other components of computer system via bus 14. It should be understood that although not shown, other hardware and/or software components could be used in conjunction with computer system. Examples include, but are not limited to: microcode, device drivers, redundant processing units, external disk drive arrays, RAID systems, tape drives, and data archival storage systems, etc.

The present invention may be a system, a method, and/or a computer program product. The computer program product may include a computer readable storage medium (or media) having computer readable program instructions thereon for causing a processor to carry out aspects of the present invention.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction implementation device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may run entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may run the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which run via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which run on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be performed substantially concurrently, or the blocks may sometimes be performed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method for configuring a metrology tool, the method comprising:
receiving a height map of a sample from an apparatus configured to generate wafer height maps, the height map indicating height information of a plurality of features on a surface of the sample, wherein the plurality of features is located on a plurality of focal planes; and
generating settings for the metrology tool based on the height map of the sample.

2. The method of claim 1, wherein generating the settings for the metrology tool comprises determining a plurality of focus settings that cause the metrology tool to focus on the plurality of focal planes.

3. The method of claim 1, wherein the height map is among a plurality of height maps, each one of the plurality of height maps corresponds to a circuit pattern formed on the sample.

4. The method of claim 1, further comprising adjusting the height map based on a height difference between a wafer stage of the apparatus and a wafer stage of the metrology tool.

5. The method of claim 1, further comprising:
identifying a specific feature on the surface of the sample;
determining a specific setting for the metrology tool that captures an image of the sample focusing on the specific feature; and
determining a plurality of settings for the metrology tool based on the specific setting and the height map.

6. The method of claim 1, further comprising storing the height map in a memory device.

7. The method of claim 1, wherein the height map corresponds to a most recent circuit pattern layer formed on the sample.

8. The method of claim 1, wherein the settings comprise a plurality of positions of a light source of the metrology tool, the plurality of positions of the light source corresponds to the plurality of focal planes, and each position among the plurality of positions of the light source causes the metrology tool to capture an image of the sample including features located on a corresponding focal plane being in focus.

9. A system comprising:
a metrology tool;
a memory;
an apparatus;
a processor connected to the metrology tool, the memory, and the apparatus;
the apparatus being configured to:
generate a height map that indicates height information of a plurality of features on a surface of a sample, wherein the plurality of features is located on a plurality of focal planes; and
send the generated height map to the processor;
the processor being configured to:
receive the height map from the apparatus; and
generate settings for the metrology tool based on the height map.

10. The system of claim 9, wherein the processor is further configured to generate the settings for the metrology tool by determining a plurality of focus settings that cause the metrology tool to focus on the plurality of focal planes.

11. The system of claim 9, wherein the processor is further configured to adjust the height map based on a height difference between a wafer stage of the apparatus and a wafer stage of the metrology tool.

12. The system of claim 9, wherein the processor is further configured to:
identify a specific feature on the surface of a sample;
determine a specific setting for the metrology tool that captures an image of the sample focusing on the specific feature; and
determine a plurality of settings for the metrology tool based on the specific setting and the height map.

13. The system of claim 9, wherein the processor is further configured to store the height map in the memory.

14. The system of claim 9, wherein the settings comprise a plurality of positions of a light source of the metrology tool, the plurality of positions of the light source corresponds to the plurality of focal planes, and each position among the plurality of positions of the light source causes the metrology tool to capture an image of a sample including features located on a corresponding focal plane being in focus.

15. A computer program product for configuring a metrology tool, the computer program product comprising a computer readable storage medium having program instructions embodied therewith, the program instructions executable by a processing element of a device to cause the device to:
receive a height map of a sample from an apparatus configured to generate wafer height maps, the height map indicating height information of a plurality of features on a surface of the sample, wherein the plurality of features is located on a plurality of focal planes; and
generate settings for the metrology tool based on the height map of the sample.

16. The computer program product of claim 15, wherein the program instructions are executable by the processing element to cause the device to generate the settings for the metrology tool comprises determining a plurality of focus settings that cause the metrology tool to focus on the plurality of focal planes.

17. The computer program product of claim 15, wherein the height map is among a plurality of height maps, each one of the plurality of height maps corresponds to a circuit pattern formed on the sample.

18. The computer program product of claim 15, wherein the program instructions are executable by the processing element to cause the device to:
identify a specific feature on the surface of the sample;
determine a specific setting for the metrology tool that captures an image of the sample focusing on the specific feature; and
determine a plurality of settings for the metrology tool based on the specific setting and the height map.

19. The computer program product of claim 15, wherein the program instructions are executable by the processing element to cause the device to store the height map in a memory.

20. The computer program product of claim 15, wherein the settings comprise a plurality of positions of a light source of the metrology tool, the plurality of positions of the light source corresponds to the plurality of focal planes, and each position among the plurality of positions of the light source causes the metrology tool to capture an image of the sample including features located on a corresponding focal plane being in focus.
